(19) United States
(12) Patent Application Publication
(10) Pub. No.: US 2024/0312812 A1
(43) Pub. Date: Sep. 19, 2024

(54) UPSTREAM PROCESS MONITORING FOR DEPOSITION AND ETCH CHAMBERS

(71) Applicant: INFICON, INC., East Syracuse, NY (US)

(72) Inventors: Matan Lapidot, Kefar-Menahem (IL); Shay Yaari, Bitzaron (IL)

(73) Assignee: INFICON, INC., East Syracuse, NY (US)

(21) Appl. No.: 18/577,147

(22) PCT Filed: Jul. 7, 2022
(86) PCT No.: PCT/US2022/036277

§ 371 Date: Jan. 5, 2024

Related U.S. Application Data
(60) Provisional application No. 63/219,032, filed on Jul. 7, 2021.

(51) Int. Cl. H01L 21/67; C23C 16/455; C23C 16/52; H01L 21/66

(52) U.S. Cl. CPC H01L 21/67253; C23C 16/45512; C23C 16/52; H01L 22/26

(57) ABSTRACT

A semiconductor fabrication system includes a mixing bowl, a distribution system receiving a mixture of gases from the mixing bowl, and a process chamber in fluid communication with the distribution system for performing a variety of semiconductor processes, e.g., deposition and etch processes, on a substrate. A plurality of mixing bowl sensors are disposed within a cavity of the mixing bowl and issue gas signals indicative of the type and flow-rate of the detected gas. Further, at least one process chamber sensor is provided within the process chamber and disposed proximal to the substrate. The process chamber sensor has a resonance property which changes upon exposure to the semiconductor process, i.e., a build-up of deposited material on a surface of the sensor, and issues material process signals indicative of the anticipated material on the surface of the substrate.

### CROSS REFERENCE TO RELATED APPLICATIONS

Pursuant to relevant portions of 35 U.S.C. § 119 and 37 C.F.R. § 1.53, this application claims the benefit and priority of U.S. Patent Application No. 63/219,032, filed on Jul. 7, 2021, the entire contents of which is hereby incorporated by reference.

### BACKGROUND

Deposition and etch processes at semiconductor manufacturing plants are widely and commonly being used during device fabrication in the semiconductor integrated circuit (IC) industry. The semiconductor industry efforts to reduce the dimensions, which traditionally were limited by the lithography resolution of 2-dimensional structures, are shifting to deposition and etch process control of 3-dimensional structures (for example, 3D gate and 3D NAND). Many times a gas mixture that contains more than one gas type is used through the sequences of deposition and etches processes as well as in prior and post steps of the main sequence. Furthermore, device critical dimensions are impacted more and more by the ability to control deposition and etch processes.

Plasma etch processes are often used to remove dielectrics, semiconductors, or metal layers by an ignition gas at a plasma state (which drive the activation energy of the chemical reaction). The material removal can also be performed by flowing reactive gases (in a non-plasma state) or through wet etch (at liquid state) stations. Deposition of films over the chamber components and the processed substrates can be applied by various methods like Plasma enhanced (PE) chemical vapor deposition (CVD), Sub atmospheric CVD, Thermal CVD, Atomic layers deposition (ALD), Plasma—enhanced atomic layer deposition and more. Etch and deposition processes can be isotropic or anisotropic (like Reactive Ion etching—RIE) depending upon the process step.

In substrate deposition processes, such as IC fabrication processes, deposition of many different layers over the wafer (which is the substrate) can be achieved through different reactions and various process matter states. Example technologies include plasma (PECVD and high density plasma—HDP), gas—sub-atmospheric CVD (SACVD) and liquid (electroplating). Some of the examples for key parameters to control the deposited layers and the device fabrication characteristics are: thickness, stress, mass, resistance, particles and refractive index. Those parameters are measured and controlled, not just for the mean value (over a wafer or a batch of wafers,) but also wafer variability and interstitial wafers variability. Reducing the process variability contributes to the improvement of the manufacturing yield at the end of line (EOL) process.

For example, the following steps are used in substrate etching: wafer etching steps to apply patterns (in conjunction with lithography steps) to the manufactured device; cleaning the wafers from contamination; creating trenches between transistors; enabling separation between contacts and isolators; reacting the wafers surface before deposition and for removal of photo resist. Key parameters to control the etch process over the wafers are: critical dimensions for the defined features, such as etch rate, thickness, stress, particles and defect control and other electrical and optical parameters.

Substrate etch and deposition may or may not be simultaneous processes (for example, in some of the HDP processes, etch and deposition may occur consecutively or concurrently) in the same process chamber, consecutively in the chamber, non-sequentially in the chamber or in different chambers.

Some of the known methods for process monitoring using integrated sensors include: mass spectrometers, optical spectrometers, RF sensors, and vacuum gauges. Such methods are, however, not localized and fail to give detailed information regarding the accumulated or removed film at different chamber locations. One example of non-localized process control includes a plasma-clean method like optical emission spectrometry, residual gas analyzers and chamber impedance measurement. All of these methods, however, measure convoluted signals from the entire chamber and do not identify the uniformity or homogeneity of the process materials at different chamber locations. Other known sensors, like temperature sensors, may be localize and read measurements along the surface of various chamber components but will not provide detailed information regarding the film conditions associated with coating these surfaces.

The current solutions to monitor issues with gas mixture or flows timing are is located in the process chamber and the exhaust line. Once the process fault (“wrong” gas mixture) reached the process chamber or the chamber exhaust it is already too late and damage to the material already occurred.

U.S. Patent Application Publication No. 2012/0201954 (Wajid) discloses a QCM that provides information regarding film coating or etch, but employs a single location which fails to provide information regarding the uniformity or homogeneity of the process at different chamber locations. Therein, the accuracy and value of the process data decreases as the size of the chamber increases.

U.S. Patent Application Publication No. 2014/0053779 (Martinson, et al.) describes a QCM probe which moves between different chamber locations. This solution, however, is limited to a research lab, and only compatible with a production environment wherein a vacuum is needed for production. In addition, this solution does not facilitate simultaneous monitoring of QCM sensors at different chamber locations.

A need, therefore, exists to: (i) identify incorrect or disproportionate gas mixtures, and (ii) control timing of deposition and etch tools to permit tighter process control during the deposition and etch processes.

### BRIEF SUMMARY OF THE DISCLOSURE

A semiconductor fabrication system includes a mixing bowl, a distribution system receiving a mixture of gases from the mixing bowl, and a process chamber in fluid communication with the distribution system for performing a variety of semiconductor processes, e.g., deposition and etch processes, on a substrate. A plurality of mixing bowl sensors are disposed within a cavity of the mixing bowl and issue gas signals indicative of the type and flow-rate of the detected gas. Further, at least one process chamber sensor is provided within the process chamber and disposed proximal to the substrate. The process chamber sensor has a resonance property which changes upon exposure to the semiconductor process, i.e., a build-up of deposited material on a surface of the sensor, and issues material process signals indicative of the anticipated material on the surface of the substrate. A controller is responsive to the gas and material process signals, to control the mix of gases in the mixing bowl and the anticipated material on the surface of the substrate.

In yet another embodiment, a method is provided for monitoring a semiconductor process. The method includes the steps of: (i) placing a plurality of mixing bowl sensors within a cavity of the mixing bowl to detect at least one gas of a gaseous material and issuing a gas signal indicative of the detected gas; (ii) distributing a flow of gaseous material into the semiconductor process chamber by a distribution system; (iii) supporting a substrate within the semiconductor process chamber and a process chamber sensor proximal to the substrate, the process chamber sensor detecting deposition and etch processes on a detection surface thereof so as to correlate the same on a surface of the substrate, and (iv) controlling the flow of gases entering the mixing bowl and the semiconductor processes performed in the process chamber to optimize the fabrication of the semiconductor circuit.

The above embodiments are exemplary only. Other embodiments as described herein are within the scope of the disclosed subject matter.

### BRIEF DESCRIPTION OF THE DRAWINGS

So that the manner in which the features of the disclosure can be understood, a detailed description may be had by reference to certain embodiments, some of which are illustrated in the accompanying drawings. It is to be noted, however, that the drawings illustrate only certain embodiments and are therefore not to be considered limiting of its scope, for the scope of the disclosed subject matter encompasses other embodiments as well. The drawings are not necessarily to scale, emphasis generally being placed upon illustrating the features of certain embodiments. In the drawings, like numerals are used to indicate like parts throughout the various views, in which:

FIG. 1 is a perspective view of a semiconductor fabrication system including a mixing bowl, a distribution system and a process chamber;

FIG. 2 is a cross-sectional view taken substantially along line 2-2 of FIG. 1; and

FIG. 3 is a cross-sectional view taken substantially along line 3-3 of FIG. 2 along a plane orthogonal to a vertical axis defined by the mixing bowl and process chamber.

FIG. 4 is a perspective view of another embodiment of the semiconductor fabrication system wherein the distribution system includes a plurality of conduits wherein at least one of the conduits distributes gas directly to a process chamber.

FIG. 5 is a perspective view of another embodiment of the semiconductor fabrication system wherein the mixing bowl sensors include a plurality of Quartz Crystal Microbalance (QCM) sensors and a plurality of optical/mass spectrometers and wherein the distribution system directs the gas mixture to a plurality of process chambers.

Corresponding reference characters indicate corresponding parts throughout several views. The examples set out herein illustrate several embodiments, but should not be construed as limiting in scope in any manner.

### DETAILED DESCRIPTION

The present disclosure relates to the field of semiconductor fabrication, including semiconductor fabrication control. More particularly, in one example, the semiconductor fabrication system employs sensors located in strategic upstream and downstream locations, i.e., in the upstream mixing bowl and the downstream process chamber to monitor semiconductor fabrication processes to augment the accuracy and homogeneity of the deposition and etch processes. For instance, disclosed herein is a unique method for monitoring the gas mixture at an upstream location, within the mixing bowl, prior to distribution by the sprinkler heads and upstream of the process chamber. Advantageously, deploying sensors at both upstream and downstream locations facilitates measurement of different material properties (mass density and stress), due to the non-homogeneity of the process within the upstream mixing bowl and downstream process chamber.

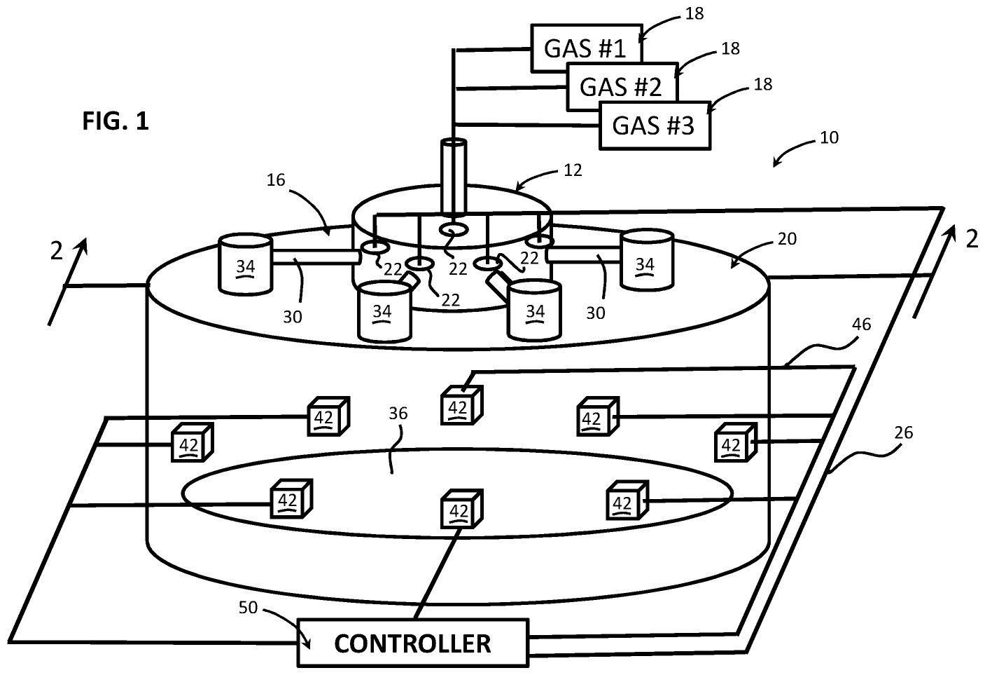

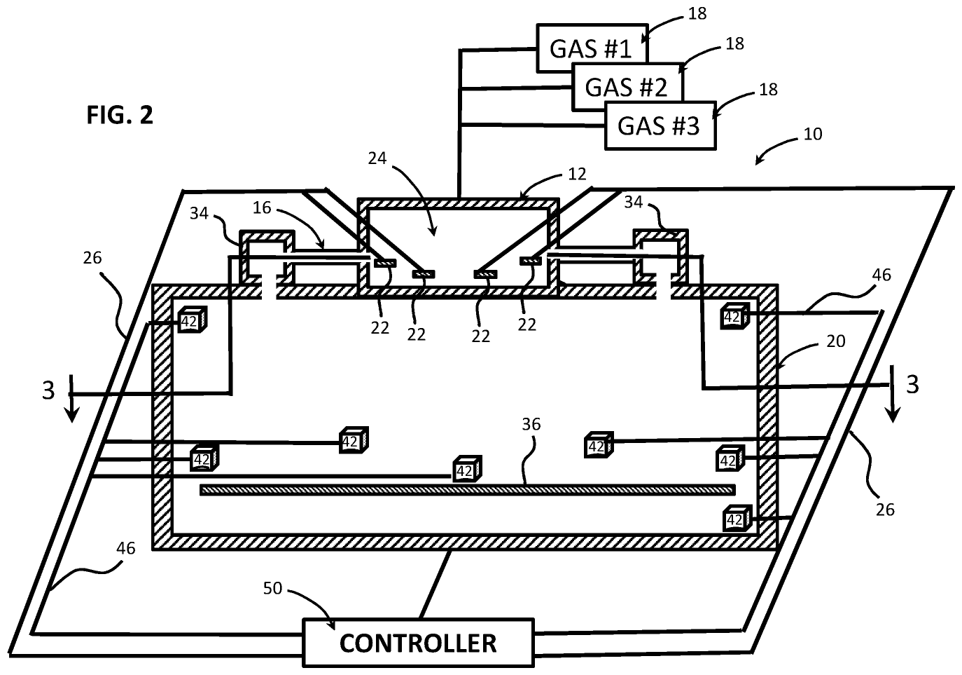

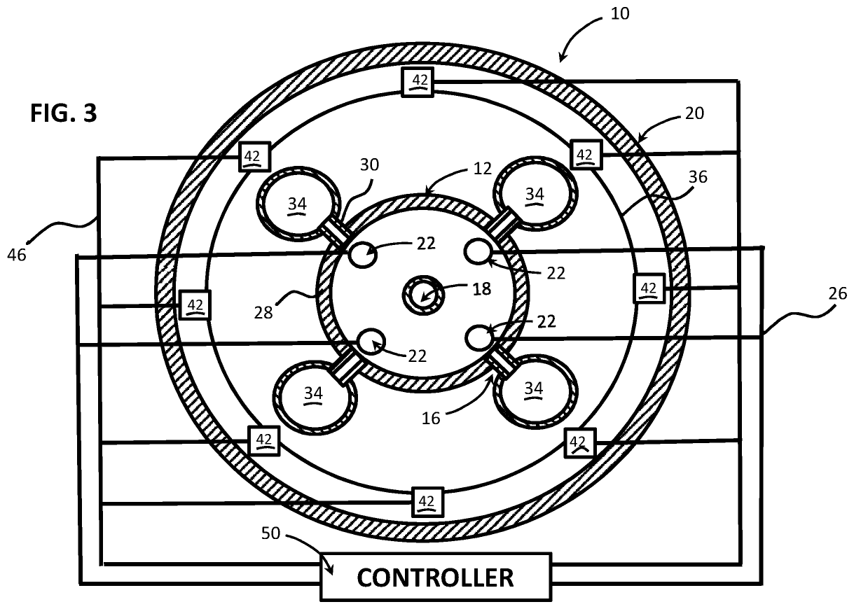

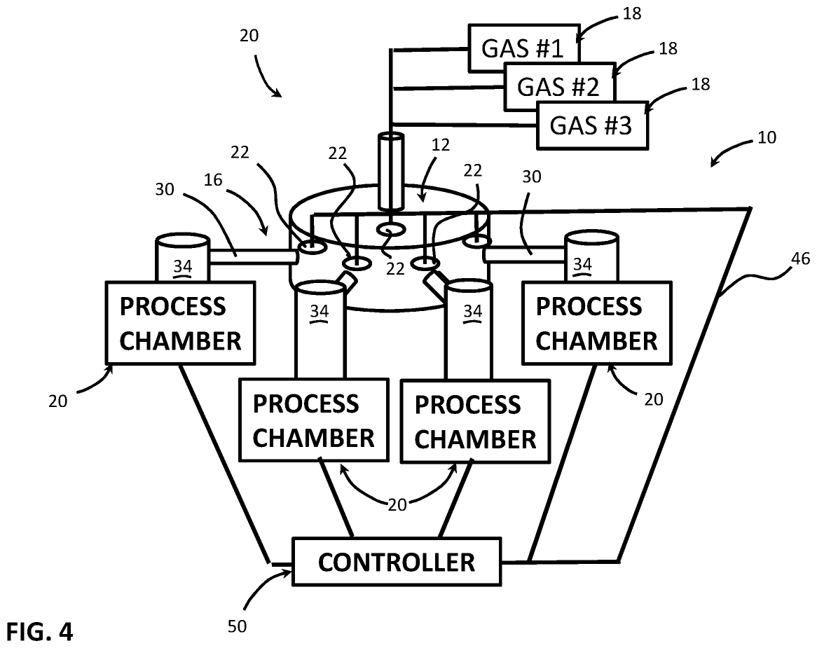

In FIGS. 1, 2 and 3, schematic perspective and cross-sectional views of the fabrication system 10 include a mixing bowl 12, a distribution system 16 in fluid communication with the mixing bowl 12, and a process chamber 20 in fluid communication with the distribution system 16. The mixing bowl 16 receives a gas mixture from several external sources 18 of gas supply and includes a plurality of gas sensors 22 disposed internally of a cavity 24 defined by the mixing bowl 16. The gas sensors 22 are described more fully below, but suffice to say at this juncture, that the gas sensors 22 detect at least one gas of the gaseous mixture and issue gas signals along lines 26. The gas sensors 22 may be evenly distributed within the mixing bowl cavity 24 however, they are preferably located proximal to each opening of the mixing bowl cavity, i.e., through the lateral or cylindrical cavity wall 28 (best seen in FIG. 3.) The openings are in fluid communication with a plurality of radial pipes or conduits 30 of the distribution system 16 which, in turn, distributes the gaseous mixture to several sprinkler heads 34 located above the process chamber 20. The distribution system 16 may include a plurality of conduits 30 in fluid communication with the mixing bowl 12 at one end and with one or more sprinkler heads 34 at the other end. Alternatively, the distribution system 16 may include one or more conduits 30 each leading directly to a dedicated process chamber 20. This embodiment is shown in FIG. 4 of the present disclosure.

Many different types of sensors may be employed in the present disclosure. For example, Quartz Crystal Microbalance (QCM) sensors or microelectromechanical (MEM) sensors may be deployed. Quartz Crystal Microbalance (QCM) sensors 22 in the mixing bowl 16 augment the deposition and etch processes being performed in the process chamber 20. A QCM sensor 22 placed in the vicinity of the area or region to be monitored provides information regarding the semiconductor processes inasmuch as it can be assumed that changes to the surface of the QCM can be correlated to the same processes being performed on a surface of the substrate 36. In one embodiment, the QCM sensor 22 has a resonance property which changes upon exposure to the semiconductor processes. The changes in mass alter the resonance response of the QCM crystal, which is indicative of the anticipated changes occurring on the substrate 36. As will be discussed in a subsequent paragraph regarding the process chamber 20 and the process chamber sensors 42, the same or similar indications may be assumed with respect to semiconductor fabrication processes within the process chamber 20. In one embodiment of the present disclosure, the QCM sensors 22 and 42 monitor process conditions like temperature, flows, pressure, etc., at a known accumulation of thickness and stress to monitor the local process conditions. Instead of a QCM sensor, a MEM sensor could be used in the same manner.

One example of a MEM sensor for use in the present disclosure is a surface acoustic wave sensor. A person of ordinary skill in the art would readily understand how QCM and MEM sensors are made and used. The present disclosure makes use of a variety of such sensors positioned at different locations in the mixing bowl 16 to identify the type, temperature, flow rate, concentration etc., of the detected gas.

Combinations of any of the following sensor types may be used as a sensor in one or more embodiments: capacitor sensors, photocathodes, photo detector sensors, micro machined ultrasonic transducers, oscillator devices configured to measure energy or mass changes, resonance electro/optical devices, resistance measurement sensors, sensors having a dielectric waveguide in contact with a metallic layer or a metallic pattern suitable to generate a Plasmonic reaction, light emitting devices, electron beam sources, ultrasonic sources, optical resonators, micro-ring resonators, photonic crystal structure resonators, temperature sensors.

By the use of QCM sensors at locations both upstream within the mixing bowl 16 and downstream within the process chamber 20, important information reflecting real time process homogeneity within the chamber and occurring on the substrate 36 can be obtained.

Measurement of process homogeneity can be obtained by measuring the QCM frequency value starting at the beginning of a deposition sequence and ending with a plasma clean sequence (for a given production recipe.) Furthermore, the difference or delta in frequency, end to start, between different runs provide critical information regarding process stability at a particular location.

Another example of process homogeneity measurement relates to the frequency difference between the beginning and the end of wafer deposition between different wafers (for the same recipe). A specific correlation parameter or equation (based on the QCM location) can be then calculated to predict the wafers thickness and thickness variability. This may help to avoid using test wafers for thickness measurement, or can be used as feed forward or backward information to control different process operations prior to, or after, substrate deposition. Instead of a QCM sensor, a MEM sensor could be used in the same manner.

Process homogeneity can also be measured by taking the maximum frequency during plasma clean from different QCM locations, which allows the user to know if a film is being accumulated under etch or over etched at a specific location. An algorithm for determining a process end point can use frequency information from multiple QCM sensors dispersed in different locations and can be used to optimize the process end point (EP) of the clean. For example, one can monitor the moving average of the frequency derivative until a threshold is reached, i.e., when the end point of the clean is reached, the derivative of the frequencies becomes much lower. For example, this over etch or under etch for different parts can be reached or achieved intentionally. The same, or similar approach, can be applied to other time-based processes using materials addition or removal, like undercoat, precoat, etc.

Endpoint detection of wafer-based processes such as deposition, etch, densification, and contaminations removal, using plasma or heat (pretreatment or bake out) can also be realized using signal inputs from multiple QCM sensors 22, 42 dispersed at different locations. QCM sensors 22, 42 at different locations inside the mixing bowl 16 and process chamber 20 can measure different deposition and etch rates to give information regarding the process uniformity.

In addition, by implementing at least two QCM sensors 22, 42 at each location, i.e., in the mixing bowl 16 and process chamber 20, each with a different angular orientation (relative to the plane of the substrate 36), the process rate at different angles over the substrate 36 can be measured and/or calculated to give three dimensional information regarding the process and process rate in the substrate plane.

The gaseous mixture is dispersed within the process chamber 20 at a variety of locations and, in the embodiment shown in FIGS. 1, 2 and 3, the gaseous mixture enters the process chamber at four (4) locations, or in each of four quadrants within the process chamber 20. As mentioned above, process chamber sensors 42 are located at several locations within the process chamber 20 and issue material process signals indicative of the semiconductor process occurring at this location.

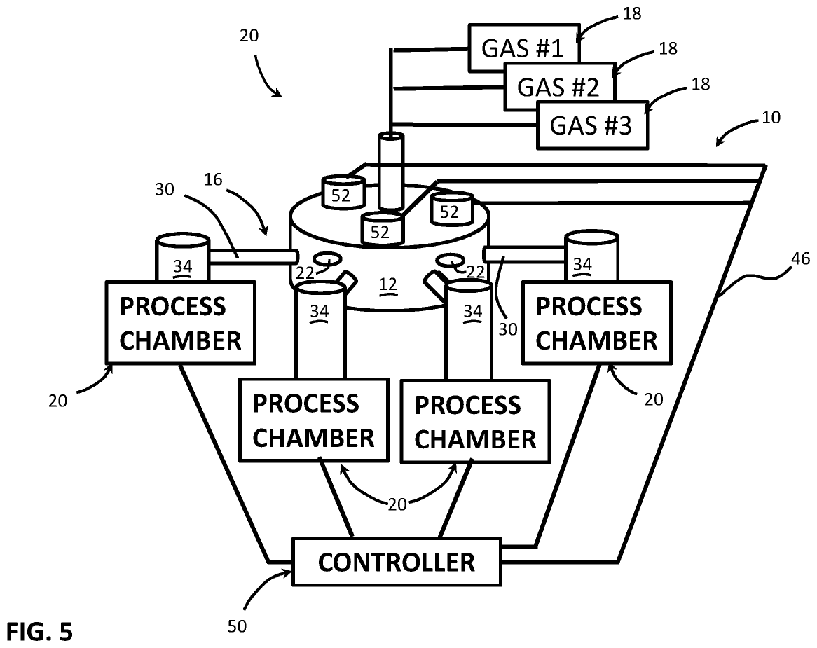

In other embodiments depicted in FIGS. 4 and 5, the mixing bowl 12 may supply a plurality of process chambers 20. Rather than a single mixing bowl 12 being dedicated to a process chamber 20, the mixing bowl 16 may feed several process chambers 20 directly. In FIG. 5, the mixing bowl 16 includes a combination of QCM sensors 22 and Optical/Mass Spectrometers 52 to provide yet additional information at location upstream of the process chambers 20. The QCM sensors are disposed about the internal periphery of the mixing bowl 16 while the Optical/Mass Spectrometers are disposed along its upper face or surface.

A controller 50 is responsive to: (i) the gas signals 26 issued by the gas sensors 22 within the mixing bowl 16, and (ii) the material process signals 46 issued by the process chamber sensors 42 within the process chamber 20 to control the mixture of gaseous material in both the mixing bowl 16 and process chamber 20. A closed loop feedback loop may be used to control the mixture, flow and concentration of the gaseous mixture entering the process chamber 20 in an effort to anticipate the material deposited on, or removed from, the surface of the substrate 36.

In summary, the semiconductor fabrication system 10 of the present disclosure provides information about the gas mixture well in advance of the process chamber 20 or in the exhaust line (not shown), where it may be already too late to correct the deficiency. Further, the present disclosure provides a semiconductor fabrication system and method therefor which facilitates the detection of incorrect gas mixtures and/or timing issues associated therewith (for example due to mal functioning of the gas valves) in the process chamber of semiconductor fabrication devices. The mixing bowl sensors (i.e., QCM or mass spectrometer sensors) may be located at the entrance to the mixing bowl 12, internally of the mixing bowl 12, or in the exhaust conduit 30 leading from the mixing bowl 12 into the sprinkler heads 34 or directly leading to the process chamber 20.

Accordingly, the semiconductor fabrication system 10 of the present disclosure provides information about the gas mixture well in advance of the process chamber 20 or in the exhaust line (not shown), where it may be already too late to correct the deficiency. In addition to the gas mixture, the semiconductor fabrication system and method facilitates identification of atmospheric or internal leaks in the gas supply lines. For example, 02 and SiH₄ can produce an exothermal reaction which can result in particulate contamination. The semiconductor fabrication system 10 of the present disclosure can detect this reaction upstream in the mixing bowl 12 to obviate damage to the system. In the same manner, the QCM sensors 22 are capable of detecting solid state or particulate contamination of the production wafers.

Additional embodiments include any one of the embodiments described above, where one or more of its components, functionalities or structures is interchanged with, replaced by or augmented by one or more of the components, functionalities or structures of a different embodiment described above.

It should be understood that various changes and modifications to the embodiments described herein will be apparent to those skilled in the art. Such changes and modifications can be made without departing from the spirit and scope of the present disclosure and without diminishing its intended advantages. It is therefore intended that such changes and modifications be covered by the appended claims.

Although several embodiments of the disclosure have been disclosed in the foregoing specification, it is understood by those skilled in the art that many modifications and other embodiments of the disclosure will come to mind to which the disclosure pertains, having the benefit of the teaching presented in the foregoing description and associated drawings. It is thus understood that the disclosure is not limited to the specific embodiments disclosed herein above, and that many modifications and other embodiments are intended to be included within the scope of the appended claims. Moreover, although specific terms are employed herein, as well as in the claims which follow, they are used only in a generic and descriptive sense, and not for the purposes of limiting the present disclosure, nor the claims which follow.

What is claimed is:

1. A semiconductor fabrication system, comprising:
a mixing bowl defining a cavity for receiving a gaseous mixture of material used for performing semiconductor processes on a substrate;
a plurality of mixing bowl sensors disposed within the cavity of the mixing bowl to detect at least one gas of the gaseous mixture of material, the sensor issuing a gas signal indicative of the detected gas;
a material distribution system for receiving gaseous material from the mixing bowl and distributing the gaseous material within the process chamber;
a process chamber for housing a substrate and at least one process chamber sensor proximal to a surface of the substrate, the process chamber in fluid communication with the material distribution system to receive the gaseous mixture of material from the mixing bowl and performing semiconductor processes on the surface of the substrate while in the presence of the at least one process chamber sensor,
the process chamber sensor having a resonance property which changes upon exposure to the semiconductor processes, the process chamber sensor issuing a material process signal indicative of the anticipated material on the surface of the substrate; and,
a controller, responsive to the gas and material process signals, to control the mixture of gaseous material in the mixing bowl and the anticipated material on the substrate.

2. The semiconductor fabrication system of claim 1, wherein the distribution system includes a plurality of sprinkler heads for distributing a flow of the gaseous mixture to a process chamber.

3. The semiconductor fabrication system of claim 1, wherein the distribution system includes at least one conduit for delivering a flow of the gaseous mixture directly to the process chamber.

4. The semiconductor fabrication system of claim 1, wherein the distribution system includes a plurality of the conduits, each of the conduits distributing a flow of the gaseous mixture to the process chamber.

5. The semiconductor fabrication system of claim 1, wherein the mixing bowl sensors include sensors from the group of: Quartz Crystal Microbalance (QCM), Optical and Mass Spectrometer sensors.

6. The semiconductor fabrication system of claim 1, wherein the material process chamber sensors include sensors from the group of: Quartz Crystal Microbalance (QCM), and MicroElectroMechanical (MEM) sensors.

7. The semiconductor fabrication system of claim 2, wherein the mixing bowl defines a circular planform having several cavity wall openings and wherein a mixing bowl sensor is disposed proximal to each cavity wall opening to detect gaseous material flowing out of the mixing bowl and toward a select one of the sprinkler heads.

8. The semiconductor fabrication system of claim 5, wherein the mixing bowl defines an opening in the cavity wall to facilitate a flow of gaseous material into each conduit, and wherein at least one of the plurality of mixing bowl sensors is disposed proximal to the cavity wall opening to detect gaseous material flowing out of the mixing bowl and toward a select one of the sprinkler heads.

9. The semiconductor fabrication system of claim 5, wherein the mixing bowl defines a cavity for containment of the gaseous mixture, and wherein at least one of the plurality of mixing bowl sensors is disposed along an upper surface of the cavity to detect gaseous material flowing out of the mixing bowl.

10. The semiconductor fabrication system of claim 1, wherein the mixing bowl defines a cavity for containment of the gaseous mixture, wherein at least one of the plurality of mixing bowl sensors is a Quartz Crystal Microbalance (QCM) disposed along an internal peripheral surface of the cavity, and wherein at least another of the plurality of mixing bowl sensors is a Mass Spectrometer sensors is a disposed along an upper surface of the cavity to detect gaseous material flowing out of the mixing bowl.

11. The semiconductor fabrication system of claim 1, further comprising a plurality of process chamber sensors, each process chamber sensor being proximal to a surface of the substrate, and wherein the material process signals are correlated in accordance with the distance and orientation of the process chamber sensors relative to the substrate to enhance the correlation data between the substrate and the process chamber sensor.

12. A method for monitoring a semiconductor fabrication process in a semiconductor process chamber receiving a mixture of gases from a gas distribution system, the gas distribution system having a plurality of sprinkler heads in fluid communication with the semiconductor process chamber at a downstream end and a plurality of conduits in fluid communication with a mixing bowl at an upstream end, the method comprising the steps of:
placing a plurality of mixing bowl sensors within a cavity of the mixing bowl to detect at least one gas of a gaseous material and issuing a gas signal indicative of the detected gas;
distributing a flow of gaseous material into the semiconductor process chamber though the sprinkler heads of the distribution system;
supporting a substrate within the semiconductor process chamber and a process chamber sensor proximal to the substrate, the process chamber sensor detecting deposition and etch processes on a detection surface thereof so as to correlate the same on a surface of the substrate.

13. The method of claim 8, wherein a resonance property of the process chamber sensor is altered upon exposure to the semiconductor process and a build-up of deposited material on the detection surface of the sensor, and further comprising the step of:
issuing a material process signal indicative of the anticipated material on the surface of the substrate.

14. The method of claim 8, further comprising the steps of:
placing a plurality of sensors within a process chamber to measure material process data occurring proximal to each of the plurality of sensors, a first sensor defining a first spatial position within the process chamber and a second sensor defining a second spatial position within the process chamber, the first spatial position having a different angular orientation than the second spatial position.
